(19) United States
(12) Patent Application Publication
(10) Pub. No.: US 2020/0318463 A1
(43) Pub. Date: Oct. 8, 2020

(54) SYSTEM AND METHOD FOR POWER CONDITIONING FOR AN ELECTRIC SUBMERSIBLE PUMP OPERATION IN AN OIL PRODUCTION FIELD

(71) Applicant: Magney Grande Distribution, Bayfield, CO (US)

(72) Inventor: Salvatore F. Grande, III, Bayfield, CO (US)

(21) Appl. No.: 16/833,040

(22) Filed: Mar. 27, 2020

Related U.S. Application Data
(63) Continuation-in-part of application No. 15/793,099, filed on Oct. 25, 2017, now Pat. No. 10,566,882.
Application No. 15/793,099 is a continuation-in-part of application No. 16/733,226, filed on Jan. 2, 2020.
(60) Provisional application No. 62/824,325, filed on Mar. 27, 2019.

(51) Int. Cl. E21B 41/00; H03H 7/06; E21B 43/12; F04B 17/03

(52) U.S. Cl. CPC E21B 41/0085; F04B 17/03; E21B 43/128; H03H 7/06

(57) ABSTRACT

A system and method for providing power to a down hole electrical submersible pump, the system including but not limited to a first 260 kVA drive module and a on a second 260 kVA drive module; a substantially optimized sine wave filter on the load side of the drive; and two harmonic filters, a first one on a first harmonic filter integrated into a first 260 kVA drive module and a second harmonic filter on a second 260 kVA.

### CROSS REFERENCE TO RELATED APPLICATIONS

This patent application is a continuation in part of co-pending patent application Ser. No. 16/733,226 entitled SYSTEM AND METHOD FOR A MITIGATING HIGH FREQUENCY COMMON MODE (L-G) PHENOMENA AND ASSOCIATED AFFECTS ON ELECTRICAL SUBMERSIBLE PUMPS MECHANICAL RUN LIFE by Grande and Shipp filed on Jan. 2, 2020 which is hereby incorporated by reference in its entirety and this patent application is based on provisional patent application Ser. No. 62/824,325 entitled A SYSTEM AND METHOD FOR POWER CONDITIONING FOR AN ELECTRIC SUBMERSIBLE PUMP OPERATION IN AN OIL PRODUCTION FIELD by Grande and Shipp filed on Mar. 27, 2019 which is hereby incorporated by reference in its entirety; and this patent application is a continuation in part of patent application Ser. No. 15/793,099 entitled SYSTEM AND METHOD FOR A MITIGATING HIGH FREQUENCY COMMON MODE (L-G) PHENOMENA AND ASSOCIATED AFFECTS ON ELECTRICAL SUBMERSIBLE PUMPS MECHANICAL RUN LIFE by Grande and Shipp filed on Oct. 25, 2017, now U.S. Pat. No. 10,566,882.

### BACKGROUND OF THE INVENTION

The Electric Submersible Pump (ESP) operation in Oil Production Fields typically requires a specific surface electrical equipment setup in order to provide power to operate the downhole pump and motor. The industry has a number of obstacles to overcome in order to provide clean power (IEEE 519-2014 Std) to the Utility and also pure sine wave power to the ESP motor. In order to provide IEEE 519 Power to the utility many configurations are used, for example, 6 Pulse VFD with Harmonic Filter, 12 Pulse VFD with Phase Shift Transformer, 18 Pulse VFD with 3 winding Phase Shift Transformer, 24 Pulse VFD with 2 each Phase Shift Transformers and Active Front End (AFE) VFDs. These configurations do not always provide IEEE 519 quality power.

### FIELD OF THE INVENTION

The present invention relates to the field of power conditioning and specifically to power conditioning for an Electric Submersible Pump.

### SUMMARY OF THE INVENTION

A system and method for providing power to a down hole electrical submersible pump, the system including but not limited to a first 260 kVA drive module and a on a second 260 kVA drive module; a substantially optimized sine wave filter on the load side of the drive; and two harmonic filters, a first one on a first harmonic filter integrated into a first 260 kVA drive module and a second harmonic filter on a second 260 kVA.

### BRIEF DESCRIPTION OF THE DRAWINGS

FIG. 1 is a schematic depiction of a generic sine wave filter;

FIG. 2 is a schematic depiction of a generic sine wave filter;

FIG. 3 is a schematic depiction of in illustrative embodiment of the present invention, having a substantially optimized sine wave filter, wherein a series resistor is added with a capacitor branch that limits the capacitor inrush when first energized eliminating instantaneous over current (IOC) nuisance tripping;

FIG. 4 is a schematic depiction of an illustrative embodiment of the present invention illustrating an equivalent impedance of FIG. 3;

FIGS. 5A and 5B are schematic depictions of Bode Plots for various selections for comparative purposes between the generic SWF and the substantially optimized system approach in an illustrative embodiment of the present invention;

FIG. 6 is a particular illustrative embodiment of the invention wherein a substantially optimized sine wave filter and common mode filter are installed on an installation on the medium voltage side of a drive without a step up transformer;

FIG. 7 is a frequency response curve for application of an optimized sine wave filter and a common mode filter wherein the frequency range is moved to attenuate harmonics in a desired range by selection of a linear inductor element, XL1 and a capacitor, Xc for a sine wave filter and a common mode filter;

FIG. 8 is a schematic block diagram depiction of an illustrative embodiment of a system implementing the invention;

FIG. 9 is a schematic depiction of an illustrative embodiment of a passive filter;

FIG. 10 is a schematic depiction of an illustrative embodiment of a sinus filter; and

FIG. 11 is plan view of an illustrative embodiment of a system implementing the invention;

FIG. 12 is a table of IEEE519 distortion limits;

FIG. 13 is a side by side comparison of before and after improvements by replacing a prior installation's components with a particular illustrative embodiment of the invention;

FIG. 14 is a side by side comparison of before and after improvements by replacing the prior installation components with a particular illustrative embodiment of the invention;

FIG. 15 is a graphical depiction of a harmonic profile without a common mode filter installed; and

FIG. 16 is a graphical depiction of a harmonic profile with a common mode filter installed.

### DETAILED DESCRIPTION OF AN ILLUSTRATIVE EMBODIMENT OF THE INVENTION

Typical Electric Submersible Pump (ESP) operation in Oil Production Fields typically require a vendor-specific surface electrical equipment setup in order to provide power to operate the specific vendor's downhole ESP pump and motor. The typical system basic setup provides a Variable Frequency Drive (VFD) and a Step-Up Transformer (SUT).

The typical prior industry ESP system presents a number of obstacles to overcome in order to provide substantially clean power (per the IEEE 519-2014 Std) to a utility grid power source grid and also a substantially pure sine wave power to the ESP motor. In order to provide IEEE 519 Power quality to the utility grid power source, numerous configurations have been utilized, for example, 6 Pulse VFD with Harmonic Filter, 12 Pulse VFD with Phase Shift Transformer, 18 Pulse VFD with 3 winding Phase Shift Transformer, 24 Pulse VFD with 2 each Phase Shift Transformers and Active Front End (AFE) VFDs. Unfortunately, these above-mentioned numerous configurations have not always provided IEEE 519 quality power to the grid.

Another obstacle presented in the prior typical ESP operations in Oil Production Fields is that an oil well is initially a large producer of fluid and the ESP pump and motor are sized for this high initial fluid production level. These prior typical ESP operations typically initially required installation of 520 kVA (600 Amp) service. As the well declined and fluid production declined, the initial horse power (HP) and Kilo Volt Ampere (kVA) requirements for the ESP pump and motor operation are substantially reduced and the original VFD becomes lightly loaded and inefficient, increasing the line side (Utility grid side) harmonics and rendering a typical load side sine wave filter substantially less effective which directly adversely affects the ESP runtimes and premature failure due to detrimental electrical power conditions. The prior typical practice in accommodating the declining power and production requirements incurred during declining fluid production, has been to replace and downsize the initial 520 kVA VFD system with a 260 kVA VFD system so that the new 260 kVA VFD system would be operating in the 70-85% loaded range, becoming efficient again in the presence of the diminished power demands and load requirements. This downsizing of the VFD system from 520 kVA TO 260 kVA required logistical support, manpower and considerable added expense to downsize and replace the 520 kVA VFD system with the new 260 kVA VFD system.

Additionally, there are Power Quality (PQ) concerns regarding the PQ that is delivered to the ESP by the inverter of the VFD system. The inverter is typically a 6-Step or Filtered Pulse Width Modulation (FPWM) Inverter. The 6-Step Inverter is unfiltered and the PWM typically has a sine wave filter. The typical prior sine wave filter is typically not an engineered product, that is, the prior sine wave filter. An engineered substantially optimized sine wave filter, as provided in a particular illustrative embodiment of the invention, factors in an impedance of an SUT in the system embodiment of the invention, and includes but is not limited to a series reactor, a shunt capacitor and an additional second series reactor. The engineered substantially optimized second series reactor utilizes and factors in the impedance of the SUT. There are many iterations of the prior generic sine wave filter among the ESP equipment providers and some are more effective than others. The inventors are unaware of a SUT impedance factored into the sine wave filter solution wherein the SUT impedance is specified.

In a particular illustrative embodiment of the invention, a system and method are provided that provide substantially improved Power Quality at the output of the inverter delivering power to the ESP. The prior generic Sine Wave Filters are typically configured as a line to line (L-L) Filter. The inventor is unaware of any PQ ESP configuration that is filtered line-to-ground (L-G) as done in an illustrative embodiment of the present invention. The L-G portion of the filtering is accomplished by installing a Common Mode Filter (CMF) applied to the Medium Voltage Side of the SUT. This CMF is described in co-owned patent Pending in co-pending patent application Ser. No. 15/793,099 entitled SYSTEM AND METHOD FOR A MITIGATING HIGH FREQUENCY COMMON MODE (L-G) PHENOMENA AND ASSOCIATED AFFECTS ON ELECTRICAL SUBMERSIBLE PUMPS MECHANICAL RUN LIFE by Grande and Shipp filed on Oct. 25, 2017, now U.S. Pat. No. 10,566,882.

In a particular illustrative embodiment of the invention, a system and method are provided that are designed to substantially overcome the obstacles presented by typical standard practices that have been previously used in the operation of ESP Systems. In a particular illustrative embodiment of the invention a containerized surface electrical package is provided that includes but is not limited to a grounding system (e.g., a Chemical Ground), Transient Voltage Surge Suppression (TVSS), a VFD with Harmonic Filtering, and a SUT with engineered impedance, a CMF, an Output VFD TVSS and a UL Listed Voltage Divider.

In a particular illustrative embodiment of the invention, the VFD is engineered to switchably shift from an initial 520 kVA rating to 260 kVA in place with a Harmonic Filtering (Utility) that maintains an IEEE 519 PQ. In a particular illustrative embodiment of the invention the system and method are also protected from Lightning and Switching Transients. The system and method provide an engineered Sine Wave Filter (also referred herein as a “substantially optimized sine wave filter”) with a properly sized first reactor, shunt capacitor and a resistor network. In a particular illustrative embodiment of the invention, a SUT is provided that is engineered to provide a proper impedance (matched Phase to Phase) in order to complete an engineered SWF package including but not limited to the SUT. The CMF is added for the line to ground (L-G) filtering of the high frequency harmonics that have in the past contributed to lowered runtimes and premature ESP failures in a wellhead feedthrough, downhole cable, splices, Motor Lead Extensions, Plug in (Potheads), motor windings and bearing fluting.

In an illustrative embodiment of the invention, the system and method are programmable so that are configured and programmed to operate with substantially all ESP Vendors downhole sensors (gauges) MODBUS protocols. Previously, a particular ESP Vendor's VFD was typically capable of operating with that particular vendor's downhole gauge, which severely limited the producer's selection of downhole equipment from other vendors and required a change in surface Power Equipment in the event of an ESP Vendor Change from that particular vendor. In a particular illustrative embodiment of the invention, the surface power equipment of the present invention operates with substantially all vendors' ESPs and downhole sensors without the necessity of changing out the surface power equipment when a change is made to an ESP and/or downhole sensor from a different vendor using a different protocol to communicate with the sensors and ESP.

In a particular illustrative embodiment of the invention, a Variable Speed Drive (VSD) with a 6-pulse input and passive filter, filtered PWM output, in an NEMA4 enclosure is provided for control and protection of electric submersible pumping units for crude oil production equipped with electric submersible inductive motors (ESM), which provides enhanced motor performance, reliability and system integration options for electric submersible pumps (ESP's).

In a particular illustrative embodiment of the invention, a VSD with passive filters is provided for suppression of higher harmonics of the current in the network, caused by the operation of the frequency converter, and compensation of reactive power is provided. A passive filter is provided as a connection of a linear inductance and a parallel resonant circuit, which includes but is not limited to series-connected inductors and capacitors. The passive filter provides a non-sinusoidal factor for the input current of not more than 5% with a non-sinusoidal factor of the main voltage of no more than 6% and a load range not lower than 70% of the nominal value in accordance with the IEEE 519 standard.

In a particular illustrative embodiment of the invention, the VSD design provides for replacement of all basic modules, functional units, circuit boards, and Reduced Power Kit in the field for less down time and rapid maintenance. All couplings and connections between units and circuit boards are detachable and demountable, thus there is no need to perform soldering when replacing any unit inside the VSD.

In a particular illustrative embodiment of the invention a sealed enclosure compatible for outdoor installation is provided along with functions performed, which include but are not limited to the below listed functions. In a particular illustrative embodiment of the invention, the functions include but are not limited to:

Smooth Electric Submersible Pump (ESP) start, full control and protection during operation;

Real-time process monitoring, analysis and control;

“Flying start” mode, which allows starting the ESP while it is back spinning decreasing down time;

Protection against ESM starting in case of backspin rotation (when “Flying start” mode is off);

Various “rocking start” modes unlock the ESP in case of mechanical jam saving time and money on round trip operations;

Maintaining process parameters (pressure, level, pump, vibration), output current and motor speed;

“Soft Start with Synchronization” algorithm holding output frequency for a present time upon the start prior to its further increase;

Motor current optimization through automatic adjustment of output voltage to frequency ratio at any given frequency;

Periodic operation between two preset frequencies, maintains oil level needed for the ESP to keep running, while keeping the oil flowing compared to on-off periodic modes where the oil could drain back if the check valve fails;

Log in controller, auto restart function, backspin protection, display unit on front door, downhole sensors support;

Read/write wirelessly all parameters from controller (and from downhole sensor), download log to USB-flash driver;

GUI selectable protocols for communicating with sensors, including but not limited to following downhole sensors: Borets, Izhevsk, TMS-1, TMS-2, WoodGroup, Triol, Phoenix, Zenith, Oxford, SKAD-2002, Centrilift, Alnas, TMSN-3, Novomet, Phoenix PICv2, SPT-2, Phoenix/Uniconn, ViewPoint, Orion, Etalon, Almaz, Solvapli, ACE, WellLift. Any and other protocols can be added by customer request.

In another particular illustrative embodiment of the invention Variable speed drive performs the following functions:

Motor switching on/off; Electric motor operation in the following modes: manual (without any capability of the ESM automatic reclosing after protection acting);

automatic with a capability of the ESM automatic reclosing (AR) and automatic reclosing by a preset time program;

Current optimization mode when a preset revolutions per minute (rpm) is reached;

Operation by a preset time program with ESM ON/OFF periods programmed separately;

Motor speed manual control using UMKA-03 controller and remote control using a supervisory control console;

Automatic change of the output frequency by a preset time program;

ESM smooth acceleration and braking with assigned rate;

Motor reversal;

Motor automatic switching on with a controlled time delay when supply voltage is applied;

Automatic keeping a setpoint for some process parameter (pressure, current or else);

Electric motor starting modes: swinging, impact start (used for unjamming submersible unit), soft start with synchronization;

Unjamming features the maximum motor torque at low speed;

Monitoring of the “cable-ESM” system isolation resistance with ESM switching-off if the resistance is decreased below the admissible level;

Operation when the “cable-ESM” system isolation resistance is decreased with the fast shutdown in case of overload;

Measurement of the actual parameters of the submersible pumping unit and VSD and their representation on a UMKA-03 display;

Motor remote control, monitoring of motor parameters, reading and changing of protection setpoints through a telemetering system using RS-485 interface; control through SCADA system using modem or direct connection (external connections compartment);

Recording of causes of ESM switching-on/off and recording the actual parameters into the integrated non-volatile memory during operation;

Recording of modified setpoints into the event log with date and time of the setpoint change;

Possibility of downloading a log file with working history to a USB-flash drive;

Outdoor light alarm system indicating the pumping unit state (run, wait, stop);

Control of the motor from a submersible device (gauge) with possibility to install surface panel inside a VSD;

Overload/underload protections, current imbalance protections, protection against unacceptable supply voltage and DC-link high voltage, against continuous low-frequency operation of VSD, against overheating of power switch cooler, and against operation with telemetering parameters beyond the preset limits, all protections may be adjusted in the field;

Information of the VSD door opening may be transferred to dispatching station through the TMS;

Measurement of electric energy consumption;

Backup power to a control system with possibility to power surface control panel of a DME;

Monitoring for availability of three phases of the power supply;

ESM is tripped or its start is disabled if a phase is unavailable;

Measuring of the VSD input electric power consumption with build in energy meter (optional); and

Harmonic compensation according to IEEE 519 standard. Consumption current capacitance <30% In.

TABLE 1

| | | Value | | |
|---|---|---|---|---|
| Parameter | Unit | AK06-MM-800 | | |
| Nominal output current | A | 800 | | |
| Reduce current | A | 400 | | |
| Rated full power for 480 V | kVA | 599 | | |
| Reduce power | kVA | 299 | | |
| Nominal output voltage | V | 0 . . . 480 − 10% | | |
| Output frequency | Hz | 1.5 . . . 80 ± 0.1% - asynchronous motor | | |
| | | 1.5 . . . 200 ± 0.1% - permanent magnet motor | | |
| Overcurrent | | up to 120% of rated value during 60 sec | | |
| Nominal supply voltage | V | 3 × 480 − 15%, +10% | | |
| Nominal supply | Hz | 60 + 1 | | |
| frequency | | | | |
| TXDu (480 V/60 Hz) | % | <=5* | | |
| TXDi (480 V/60 Hz) | % | <=5* | | |
| Output section | | Built-in output sine filter | | |
| Efficiency VSD, not less | % | 97 | | |
| than | | | | |
| Efficiency passive filter, | | 98 | | |
| not less than | | | | |
| Filter current | % | 30% In | | |
| capacitance, not less than | | | | |
| Controller | | UMKA03 Controller with 6″ screen | | |
| Interfaces | | 2 analog inputs; 0 . . . 10 V DC, 4 . . . 20 mA | | |
| default | | 2 digital inputs; 24 V DC | | |
| | | 8 differential analog inputs: | | |
| Additional blocks (option) | | 4 . . . 20 mA, 0 . . . 10 V, 0 . . . 5 V | | |
| | | 4 digital inputs: 24 V DC | | |
| | | 4 analog outputs (±10 V DC; 0 . . . 20 mA; 4~20 mA) | | |
| | | I Drive GPRS Router | | |
| Serial ports | | 2 x RS485 ; 1 x RS232 ; 1 x USB, Ethernet (optional) | | |
| Cooling | | Forced air | | |
| Position | | Vertical (on the ground) | | |
| Protection level | | NEMA4 | | |
| Ambient temperature | ° C. | Storage | Transport | Operation |
| | | −20 . . . +70 | −20 . . . +70 | −20 . . . +60 |
| Relative humidity | | 100% | | |
| Altitude above Sea level | m | 1000 | | |
| Vibration load | m/c² | 5 | | |
| Impact load | m/c² | 30 | | |
| Certification and | | CE | | |
| standards compliance | | | | |
| * according to IEEE 519 standard | | | | |

FIELD DESCRIPTION
AK06 Variable speed drive for ESP applications

-
Multipurpose motor (asynchronous submersible motors, permanent magnet

```
  MM
  submersible motors)
  - XXX
```

-

Output drive current
800 - 800 Amps (with a possibility to reduce power down to 400 Amps - RPK required)

FIELD DESCRIPTION

| 7 Input section 7 - VSD with input passive filter | |
|---|---|
| 1 Built-in output sine filter | |
| 0 Without drive bypass | |
| 2 | NEMA4, Climate rating upon the requirements of the |
| | customer |
| | - |
| | 20... |
| | +60 |
| | ° C. |
| 3 | With UMKA-03 controller |

8 With power reduce kit
-

480 Supply voltage - 480 V

In a particular illustrative embodiment of the invention, a Step-Up Transformer (SUT) is provided. The SUT is a Liquid-cooled, isolation, two winding, three-phase transformer, suitable for use in a variable-frequency drive step-up application on an off-shore oil platform or in an electro center house with air conditioning in a desert setting. In a particular illustrative embodiment of the invention, the ratings of the transformer are substantially as follows:

| | |
|---|---|
| KVA | 260 and 520 kVA OA (quote both) |
| Phases 3 | |
| Frequency | 6-90 Hz (35-75 Hz nominal operating range) |
| Primary Voltage | 480 V |
| Primary Winding | Delta |
| Configuration | |
| Primary BIL | 30 kV |
| Secondary Voltage | 2400 V delta or 4160 V wye * |
| Taps | +4 and −8 (13 positions total)* |
| Secondary Configuration | Delta or Wye |
| Secondary BIL | [symbol] 60 kV |
| Taps | Multiple (provide nameplate drawing) |
| Temperature Rise | 55 [symbol] C./65 C. (100% 55 C./112% 65 C.) |
| Impedance | 5.5% or less (5%-6% range) |
| **K Factor | 4.0 |
| Altitude | Sea level (<3,300 ft standard design) |

In a particular illustrative embodiment of the invention, the SUT transformer is applied in an Electrical Submersible Pump application. The vendor may quote a more standard tap voltages range, consistent with this industry but will state so in their offering and list the taps being supplied. Nominal will be to accommodate 1400V VLL at surface all the way to 4600V at the surface. The SUT unit is provided with an approved fire-retardant rating suitable for indoor use (for example, FR3, etc. that is bio-degradable). It may or may not be indoors but is still suggested for platform use. The transformer carries a continuous rating with average winding temperature rise that shall not exceed 55 degrees C., based on an average ambient of 55 degrees C. over 24 hours with a maximum of 40 degrees C. ambient. The transformer is designed to meet the sound level standards for liquid transformers as defined in NEMA TR1. The transformer is designed and manufactured in accordance with all applicable NEMA and ANSI standards. The main transformer tank and attached components are designed to withstand pressures +/−7 psi without permanent deformation. Each radiator assembly is individually welded and receives a quality control pressurized check for leaks. The entire tank assembly receives a similar leak test before tanking. A final six-hour leak test is performed after the transformer is tanked, welded and completed to substantially ensure that there are no leaks before shipment. High-voltage and low-voltage windings are preferably copper. Alternatively, aluminum is used in the High-voltage and low-voltage windings. The transformer is constructed suitable for floor mounting. The enclosure includes but is not limited to lifting provisions and channel base and provides an adder to provide an internal transformer shield located between each phase of the HV and LV windings. The transformer shield overlaps itself but is insulated at the lap (thus no shorted turn). In a particular embodiment, the transformer has a single-point grounded to the same point as the core ground. The iron core is single-point grounded internally with a removable ground strap at a sealed access port.

In a particular illustrative embodiment of the invention, the transformer primary and secondary connections are located side by side or on opposite sides of the tank. Terminal compartments are air-filled with individual doors with provisions for a single padlock. Doors are equipped with lift-off type hinges. If terminal compartments are located side by side, a grounded metal barrier separates the high voltage and low voltage sections, and each section forms a sealed compartment when the cover is closed. Bushings are arranged for vertical take-off from horizontal bushings. Three horizontal low-voltage bushings are provided. Low voltage bushings are epoxy or approved equivalents. Six horizontal high-voltage bushings are provided—2 for each winding individually. High voltage bushings are epoxy or porcelain. For a wye configuration, 2 jumpers are added to make up the wye point within a terminal chamber. All e-energized taps are available via a tap changer(s) mechanism (or 2 mechanisms). Jumpers are provided to connect the medium voltage winding either delta or wye. A copy of the detailed connection instructions is located internal to the door covering. They are also be located on the external nameplate. The tap voltages are listed below in Table 2.

TABLE 2

| Delta | Wye |
|---|---|
| 1600 V | 2771 V |
| 1700 V | 2944 V |
| 1800 V | 3118 V |
| 1900 V | 3291 V |
| 2000 V | 3464 V |
| 2100 V | 3637 V |
| 2200 V | 3637 V |
| 2300 V | 3984 V |
| 2400 V | 4160 V |
| 2500 V | 4330 V |
| 2600 V | 4503 V |
| 2700 V | 4676 V |
| 2800 V | 4850 V |

Per Table 2, above, each winding provides 100V steps between taps. These steps become 173V steps in the wye configuration. The full transformer kVA ratings apply to the wye connections. The delta configuration also provides reduced kVA ratings (limited by the ampere rating of the winding in the wye connection). Alternate voltage taps are provided based on what is normally provided to the oil field industry. ANSI case grounding provisions are provided in each bushing compartment and on the external base of transformer tank. These grounding pads are welded to the tank.

In a particular illustrative embodiment of the invention pulse width modulation (PWM) type drives are provided as the workhorse choice for drives used on Electrical Submersible Pumps world-wide. However, due to the nature of the ESP, it cannot easily or economically be designed as an “inverter duty” motor. Therefore, the standard surface application solutions do not work well and/or are not practical, which substantially eliminates using unfiltered PWM drives on ESP's. The few times they have been used, have resulted in runtimes of only a few months before ESP failure.

Therefore, in a particular illustrative embodiment, output filtering is provided to make the drive output waveforms substantially closer to a real sine wave form—that the motor wants to see. Since ESP's are specialty motors in a very hostile environment and several thousand feet away from the drive, a standard “one-size-fits-all” based on initial price, is a less than a desirable filtering choice. As such, in a particular illustrative embodiment of the invention, an engineered substantially optimized filtering package is provided that has been proven to significantly extend electrical run life for ESPs.

In a particular illustrative embodiment of the invention, a substantially optimized output Sine Wave Filter (“SWF”) is provided. The substantially optimized SWF includes but is not limited to 3 major elements. A first element is a series reactor, XL1 followed by a shunt capacitor C branch (a second element). A third element is a second series reactor, Xsut, XL2. A fourth element is a common mode filter (CMF) (stand-alone element) working in cooperation with a novel well-designed substantially optimized SWF, rounds out the complete system of filtering.

With low voltage drives, the careful selection of the SUT impedance equals the second series reactor, Xsut, XL2. Other components are added for improved power quality in the offering, but these are not a substantial factor in the filtering aspect. The “engineered” or also referred to herein in as “substantially optimized” SWF and careful selection of the electrical characteristics of all three elements working together as a system in a typical ESP environment, substantially extends the electrical run-life of the ESP system by reducing the ESP system's expose to harmful high frequency voltage harmonics.

Harmonic control and reduction on the utility grid source side is also provided by a particular illustrative embodiment of the invention. In a particular illustrative embodiment of the invention, a variety of methods of cost effective harmonic controls are provided to meet IEEE 519 harmonic standards at the point of common coupling (PCC)—generally on the primary side of the step down transformer (SUT). In particular illustrative embodiment of the invention, phase multiplication between wells with step down transformers connection choices is provided along with a 12 pulse or higher, depending on size of drive, series matrix input filters and an active front end.

For Low Voltage drives, output sinewave filter with series reactor (XL1); Shunt branch ungrounded capacitor with a series resistor; second reactor in the form of the impedance of the step up transformer (Xsut); addition of the CMF, the developed Common Mode Filter on the medium voltage side of the SUT, along with Input and output Surge protective devices and Output High Resistance Grounding.

FIG. 1 is a schematic depiction 100 of a conventional typical generic Sine Wave Filter (SWF) 102 that currently is provided by multiple manufacturers. The generic SWF is generally based on 1 size fits all within a kVA drive range and lowest cost. As such, these generic SWFs leave the resistor out of the SWF and undersize the reactor as much as possible to provide cost reduction. As a SWF, most typical generic SWFs are marginally effective with the ESP only lasting on the order of 6 to 18 months on average before having to be replaced, based on field measurements, interviews with many end users and design reviews. In these typical generic SWFs, leaving the resistor out reduces costs and does not incur watt losses (energy) of heat generated by the resistor, which helps to minimize initial costs, but the typical generic SWFs do little for to extend ESP Run Life.

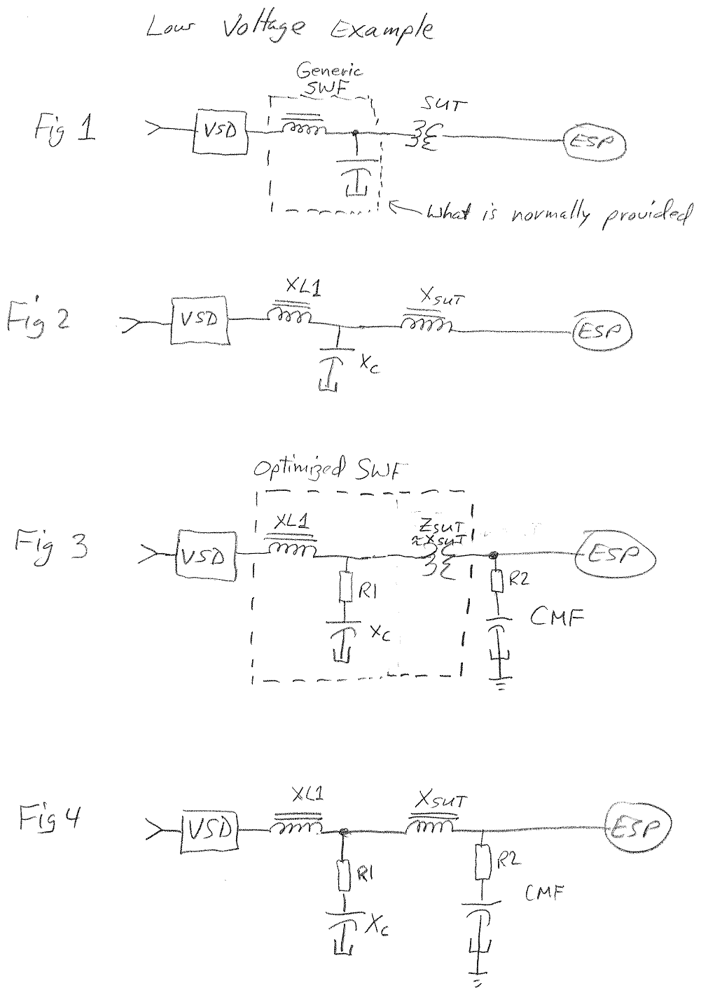

FIG. 2 is a schematic depiction 200 of an equivalent impedance diagram of the schematic depicted in FIG. 1 ignoring the transformer turns ratio, etc. Note that the shunt capacitor branch 202 is ungrounded. If one were to solidly ground the capacitor wye point, this would cause serious drive output issues with the insulated-gate bipolar transistor (IGBT)'s. Moreover, an ungrounded filter does not substantially reduce the line to ground (common mode) frequencies.

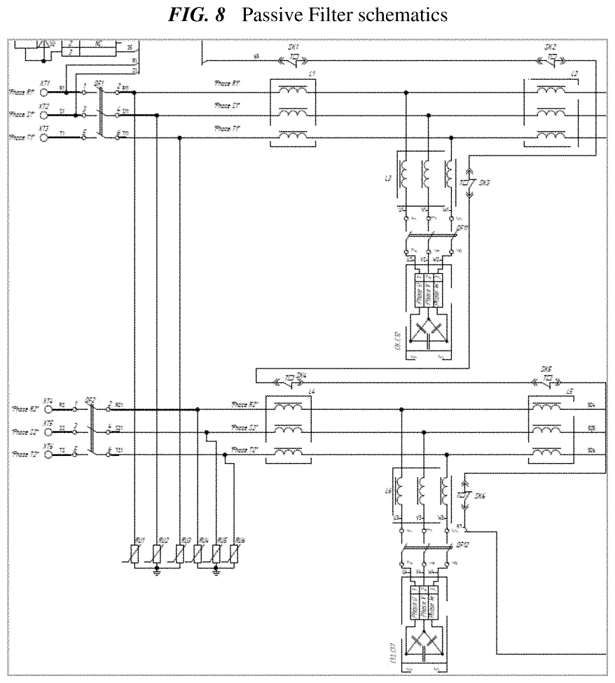

FIG. 3—In a particular illustrative embodiment of the invention 300, a series resistor 302 is provided in the capacitor branch of an SWF. This resistor limits the capacitor inrush current when first energized substantially eliminating the instantaneous over current (IOC) nuisance tripping. The series resistor 302 provides for selection of a substantially optimize reactor and capacitor sizing for a substantially improved PQ output. See, for example FIG. 5. In FIG. 5, The Bode Plot shows how an uncontrolled Xsut (SUT impedance) can work against PQ and amplify higher order harmonics within a certain range. In electrical engineering and control theory, a Bode plot is a graph of the frequency response of a system. It is usually a combination of a Bode magnitude plot, expressing the magnitude (usually in decibels) of the frequency response, and a Bode phase plot, expressing the phase shift. The sine waver filter is a line to line filter. The CMF is a line to ground filter. In a particular illustrative embodiment of the invention, the components for the substantially optimized sine wave filter are for a particular drive are:

carrier frequency (switching frequency of drive): 4 kHz;

inductance: 36 microhenry;

capacity 3*23*7=483 microfarad;

roll off coefficient: 10;

resonance modulation: 1207 Hz; and

THD (output current, amperage): less than 5%.

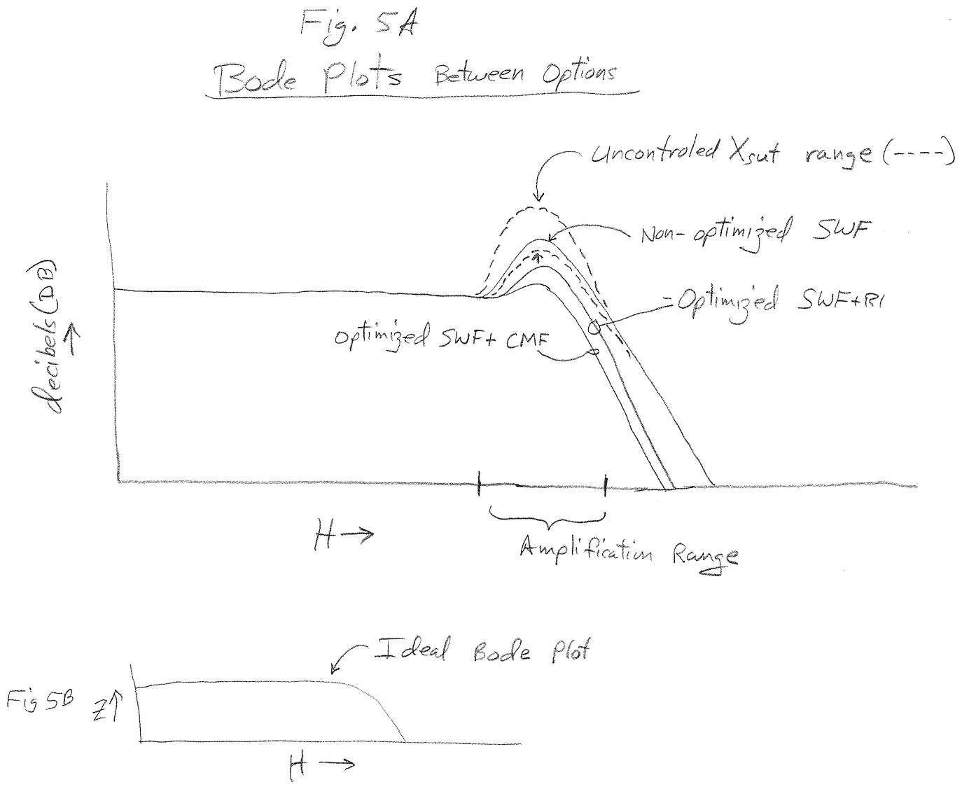

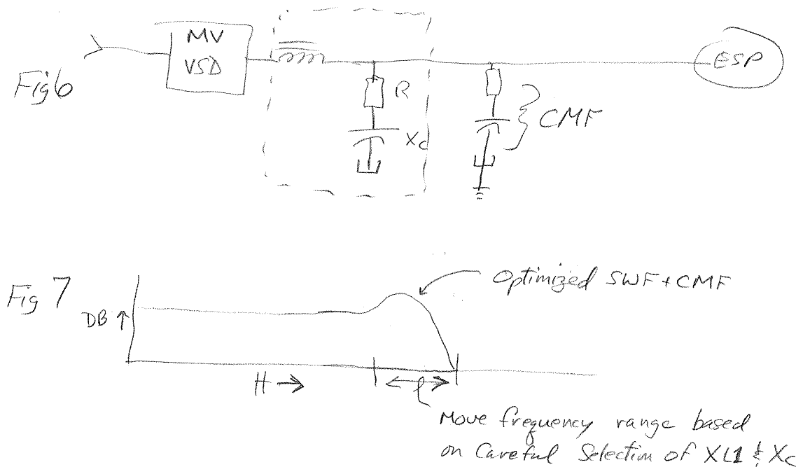

FIG. 4—is a diagram 400 of an equivalent impedance of the circuit depicted in FIG. 3. Note that in this case, the SUT impedance is also carefully selected since a true SWF consists of 2 series reactors as shown in FIG. 4 with a shunt capacitor branch. In a particular illustrative embodiment of the invention, a carefully selected the SUT impedance (e.g., 5%) along with the other substantially optimized SWF components are provided to substantially improve the complete substantially optimized SWF performance.

FIG. 5 is a schematic depiction of a Bode Plot of the various selections for comparative purposes between the generic SWF and a substantially optimized SWF in an illustrative embodiment of the system and method of the invention. The generic SWF is shown. Without a resistor, the undersized reactor has significant choice limitations of sizing the shunt capacitor. To make the capacitor large enough with this approach to result in reasonable output waveforms, would cause the drive to nuisance trip on Instantaneous Over Current (IOC) when first energized due to capacitor inrush current, which inhibits bringing the drive online. In a particular illustrative embodiment of the invention, a resistor is provided to substantially eliminate the IOC nuisance tripping and that allows substantially optimized XL1 and Xc values for an improved performing SWF. The energy losses in the resistor are minimal compared to the energy used by the drive for ESP purposes and costs attributed to shortened run-life due to improper filtering of high frequency harmonics. Next, the SUT impedance is provided to meet the second reactor requirements. A Common Mode Filter (CMF) is provided to substantially reduce substantially all of the higher order harmonics that cause high frequency failures as presented in the prior filed co-pending nonprovisional patent application noted above.

As shown in the FIG. 5 Bode plot, each of the selections added improves the PQ output by substantially eliminating amplification in substantially any frequency range as far as what goes down hole to the ESP.

FIG. 6 is a depiction of a particular illustrative embodiment of the invention wherein a substantially optimized sine wave filter and common mode filter are installed on an installation on the medium voltage side of a drive without a step up transformer;

FIG. 7 is a frequency response curve for application of an optimized sine wave filter and a common mode filter wherein the frequency range is moved to attenuate harmonics in a desired frequency range by selection of XL1 and Xc for a sine wave filter and a common mode filter in a particular illustrative embodiment of the invention;

FIG. 8 is a schematic block diagram depiction of an illustrative embodiment of a system implementing the invention. FIG. 8 is a schematic depiction of an illustrative embodiment of a system 600. Turning Now to FIG. 8, in a particular illustrative embodiment of the invention the system includes but is not limited to a housing 601 containing two 260 kVA inverter/rectifier drives 606, 607 and two harmonic filters 604, 605 on the input side of the drive. Each one of the two 260 kVA inverter/rectifier drives are provided with its own integrated harmonic filter (HF) on the input side of the drive. Each of the 260 kVA inverter/rectifier drives (also referred to herein as a “drive”) with HF provides IEEE 519 to a utility 602 providing power over line 604 to the modular drive 615 and each of the 260 kVA drives 606, 607 on the input side of each drive. In a particular illustrative embodiment of the invention, an engineered SWF as described herein is provided on the output side of the drive. A SWF 608 is provided to filter the voltage output of each drive. A processor 612 and attached computer readable medium (CRM) 613 are provided to generate a graphical user interface (GUI) on a display attached to the processor for switchable selection a system configuration. Either one of the two drives 606, 607 can be placed online or offline by the GUI. Each drive has an integrated harmonic frequency filter 604, 605. A switchable capacitor 616 in the CMF is switched into the CMF circuit when desired for additional power filtering. A MODBUS protocol for a particular vendor, stored in the CRM is selected for a particular vendor's ESP sensor from the GUI. In a particular illustrative embodiment, the output voltage from the SWF or from the CMF 617 when a CMF is included in the system. In particular illustrative embodiment of the system, a computer program stored in the CRM performs the method and operates and configures the system of the present invention. The output of the computer program sends data down a wire 609 to power and communicate between an ESP 610 and an ESP gauge 611. The processor and the ESP and sensors send data and receive data between each other and thus are referred to herein as “in data communication”.

Thus, when power requirements are reduced as the pumping demand declines, one of the two 260 kVA drives are switched off from the processor and the remaining 260 kVA drive remains active but continues to provide IEEE 519 power to the utility using its own integrated HF. Thus, an illustrative embodiment of the present invention includes but is not limited to a modular drive including but not limited to two 260 kVA drives, each with an integrated HF. One 260 kVA drive with its own integrated HF is joined with a second 260 kVA drive with its own integrated HF as two modules of a modular 520 kVA drive. The modular 520 kVA drive enables meeting initial power and HP pumping demands at 520 kVA using the combination of the first and second 260 kVA drive modules and enables switchable configuration of the 520 kVA modular drive to one 260 kVA drive module when initial power demands diminish to service the ESP at the lower 260 kVA power rating while maintain a high power factor above 0.95 and IEEE 519 power to a utility providing power to the modular drive.

In another particular illustrative embodiment of the invention, a switchable universal controller selectable from a graphical user interface providing a drop down menu to select a particular MODBUS communication protocol for a particular vendors downhole ESP gauge and sensors. Thus, a particular vendors sensor protocol is selected from a graphical user interface presented by the processor so that a user selects the MODBUS protocol for a particular vendor's sensor. In the past, a particular vendor's downhole ESP was provided with a vendor supplied up hole controller that used the particular vendor's specific protocol to communicate with the vendor's down hole ESP and gauges. Thus, when a producer wanted to change out a first ESP from a first vendor to a second ESP from a second vendor, the producer had to purchase both the up hole controller and the ESP from the second vendor because the first vendor's up hole controller would not communicate with the second vendor's ESP. In a particular illustrative embodiment of the invention, the universal controller (also referred to herein as a “processor”) is provided that is switchable from the GUI to communicate with either the first vendor's ESP or the second vendor's ESP with each vendors specific MODBUS protocol.

Thus, when the producer installs the universal controller up hole, there is no need to change the up hole controller when changing vendors. The producer selects a first MODBUS protocol on the GUI for the first vendor's ESP and selects a second MODBUS protocol on the GUI for the second ESP when the producer replaces the first vendors ESP with the second vendor's ESP. In a particular illustrative embodiment of the invention the universal controller communicates with a particular vendors ESP with the particular vendor's MODBUS protocol to receive and send electrical signals over a hard wire communication link between the ESP and the universal controller to receive and send data representing ESP gauges and sensors information and commands. In a particular illustrative embodiment of the invention, the data representing ESP gauges and sensors information and commands, includes but is not limited to data from the ESP, for example, ESP motor temperature, intake temperature, intake pressure, discharge pressure and three-axis (x, y, z) vibration.

In another particular illustrative embodiment of the invention, a CMF as described in co-pending patent application Ser. No. 15/793,099 is provided on the modular 560 kVA drive. In another particular embodiment of the invention, a switchable capacitor is provided in the CMF to add capacitance to the CMF when power and HP requirements are reduced from 560 kVA to 260 kVA to improve the performance of the CMF at lower power.

In the past, vendors have supplied a generic sine wave filter (SWF) in their systems that provided power downhole to their ESPs. Their generic SWFs typically knocked off the peaks to approximate a sine wave but did little to improve a PQ of the electrical and power characteristics of the power supplied to the ESP. The generic SWF's lack of handling the power characteristics led to premature ESP failures that often failed within 6 months and had to be replaced. Replacing the ESP used to require a producer to shut down production to remove and replace a failed ESP. Shutdowns of the nature are costly, on the order of $200,000. The prior generic SWF failed to account for the problems caused by the lack of the generic SWF to address the electrical problems that caused the premature ESP failures.

In a particular illustrative embodiment, a substantially optimized SWF is provided that specifies the impedance of the SUT which is part of the electrical characteristics of the load side of the drive supplying power to an ESP. In a particular illustrative embodiment of the invention, a SWF is provided that accounts for the impedance of the SUT (e.g., 5%), treating the impedance of the SUT as a second series reactor that cleans up power and electrical characteristics of the power supplied from the drive to the ESP and substantially extends a run life of the ESP.

In a particular illustrative embodiment of the invention, the 560 kVA modular drive is provided along with a novel substantially optimized SWF and a CMF in a housing. The combined system is provided in the housing and is referred to as a “POWERHOUSE” (TRADEMARK). In an illustrative embodiment of the invention, the system also provides a good ground for the electrical drive components of the system (Drive, CMF) and lightning protection. In a particular illustrative embodiment of the invention, the system provides a substantially consistent 0.95 and above power factor (PF) which enables a producer to group more electrical devices on the same electrical power distribution bus than would be possible with another product that was only delivering a 0.7 power factor. For example, a producer could 7 devices at a 0.95 power factor, instead being limited to 5 devices at 0.7 power factor that is provided by a prior system.

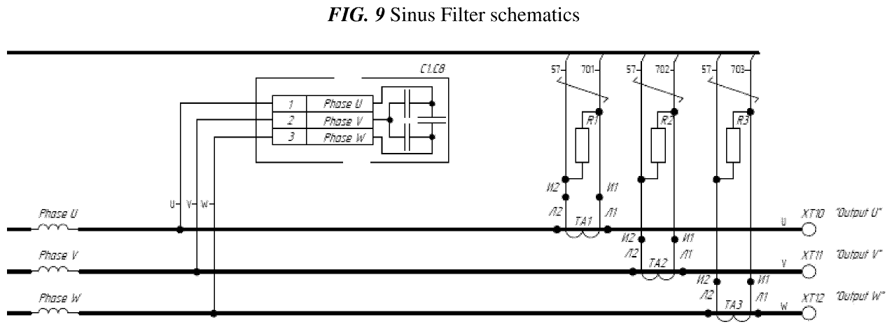

FIG. 9 is a schematic depiction of an illustrative embodiment of a passive filter in a particular illustrative embodiment of the invention.

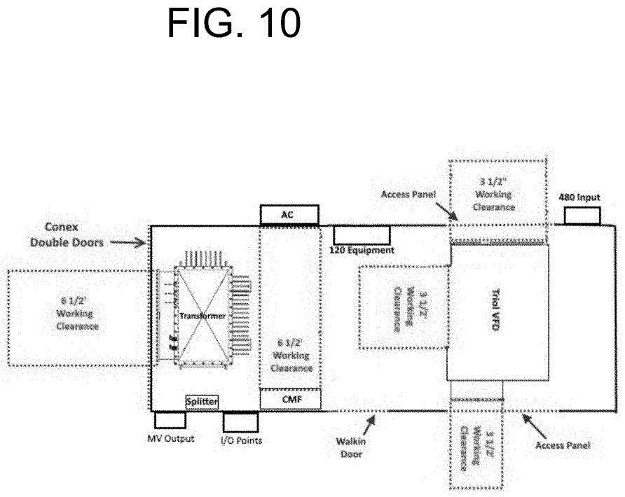

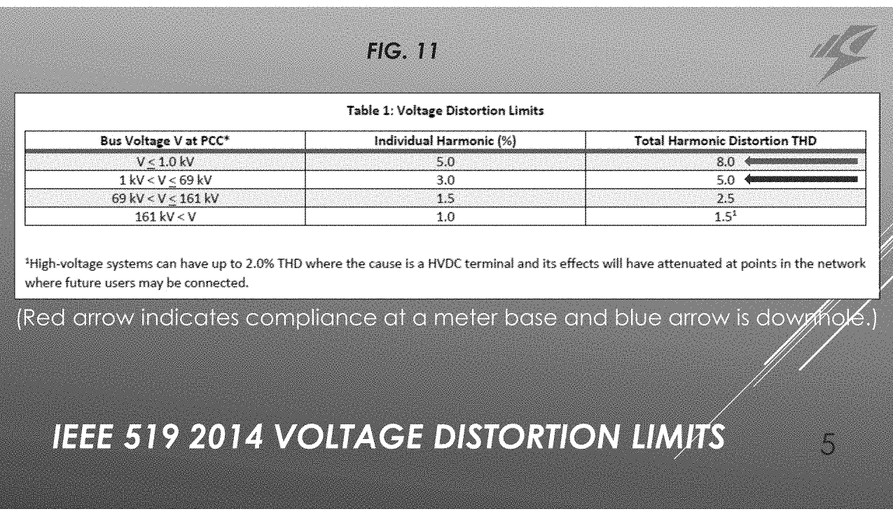

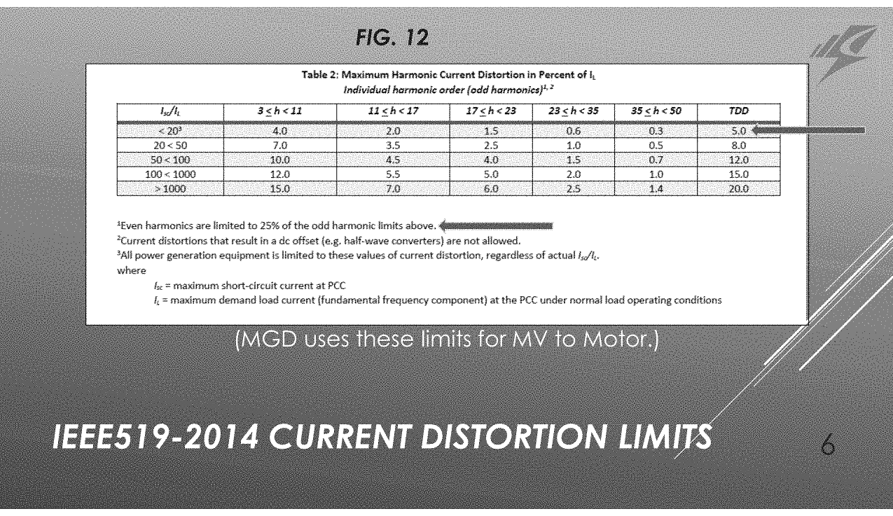

Turning now to FIGS. 10-16, FIGS. 10-16 schematically demonstrate the improvements provided by a particular illustrative embodiment of the invention. FIG. 10 is a schematic depiction of an illustrative embodiment of a sinus filter in a particular illustrative embodiment of the invention.

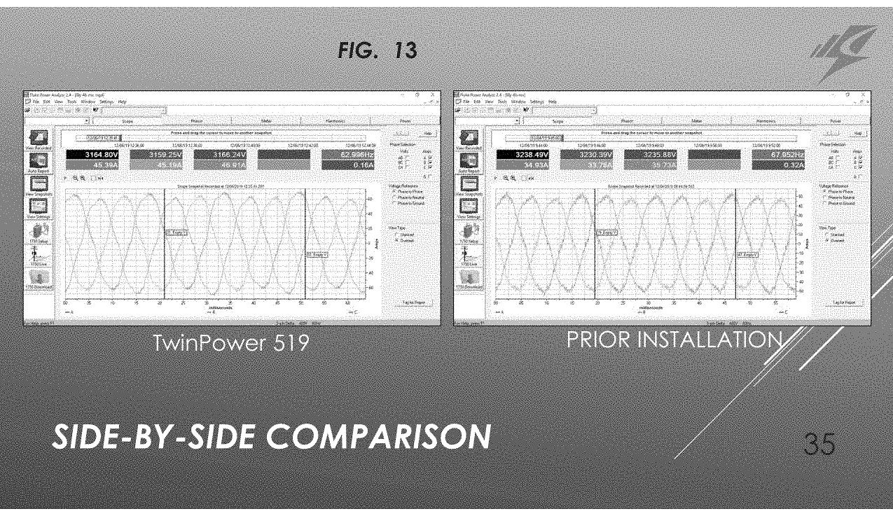

FIG. 11 is plan view of an illustrative embodiment of a system implementing the invention in a particular illustrative embodiment of the invention.

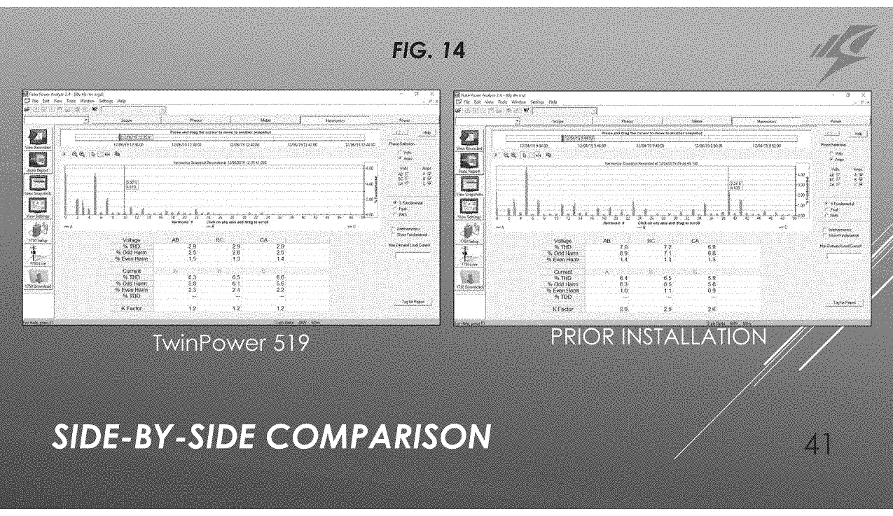

FIG. 12 is a table of IEEE519 distortion limits.

FIG. 13 is a side by side comparison of before and after replacing the prior installation components with a particular illustrative embodiment of the invention in a particular illustrative embodiment of the invention.

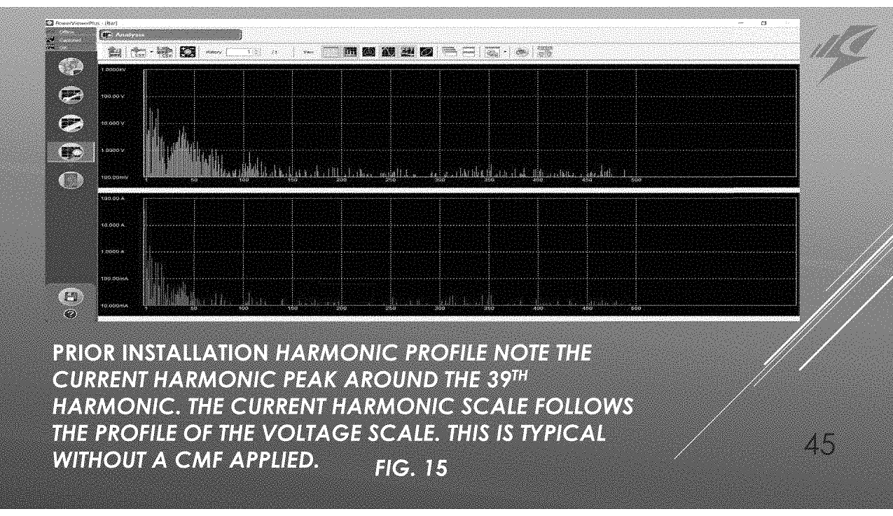

FIG. 14 is a side by side comparison of before and after replacing the prior installation components with a particular illustrative embodiment of the invention in a particular illustrative embodiment of the invention.

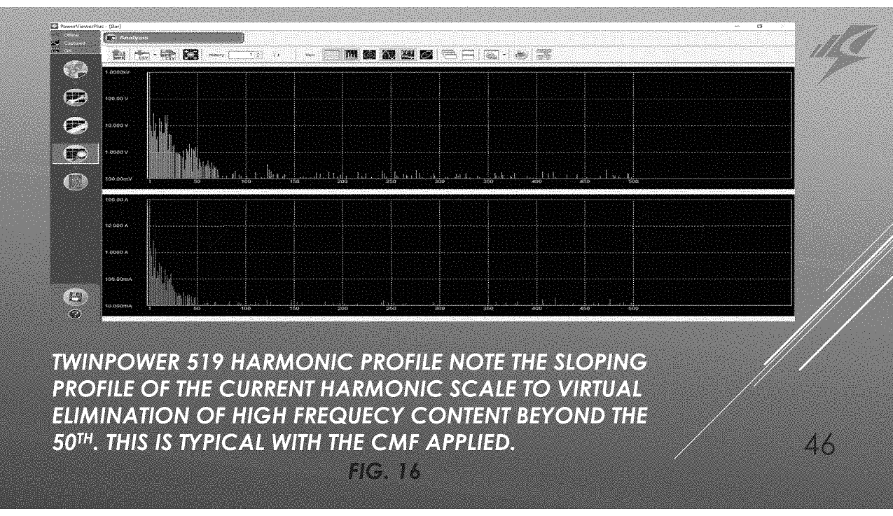

FIG. 15 is a graphical depiction of a harmonic profile without a common mode filter installed in a particular illustrative embodiment of the invention.

FIG. 16 is a graphical depiction of a harmonic profile with a common mode filter installed in a particular illustrative embodiment of the invention.

The present inventions include functions that can be realized in hardware, software, or a combination of hardware and software. In a specific embodiment, a system according to the present inventions can be realized in a centralized fashion in one computer system, or in a distributed fashion where different elements are spread across several interconnected computer systems. Any kind of computer system or other apparatus adapted for carrying out the methods and inventions described herein may be used for purposes of the present inventions. A typical combination of hardware and software could be a general-purpose computer system with a computer program that, when being loaded and executed, controls the computer system such that it carries out the methods and inventions described herein.

The figures herein include block diagram and flowchart illustrations of methods, apparatus(s) and computer program products according to various embodiments of the present inventions. It will be understood that each block in such figures, and combinations of these blocks, can be implemented by computer program instructions. These computer program instructions may be loaded onto a computer or other programmable data processing apparatus to produce a machine, such that the instructions which execute on the computer or other programmable data processing apparatus may be used to implement the functions specified in the block, blocks or flow charts. The flow chart is an example only and the steps shown in the flow chart need not be executed in the exact order shown on the flow chart. Moreover, some of the steps in the flow chart can be left out in performing the system and method of the present invention. These computer program instructions may also be stored in a computer-readable medium or memory that can direct a computer or other programmable data processing apparatus to function in a particular manner, such that the instructions stored in the computer-readable medium or memory produce an article of manufacture including instructions which may implement the function specified in the block, blocks or flow charts.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions specified in the block, blocks or flow chart. Those skilled in the art should readily appreciate that programs defining the functions of the present inventions can be delivered to a computer in many forms, including but not limited to: (a) information permanently stored on non-writable storage media (e.g., read only memory devices within a computer such as ROM or CD-ROM disks readable by a computer I/O attachment); (b) information alterably stored on writable storage media (e.g., floppy disks and hard drives); or (c) information conveyed to a computer through communication media for example using wireless, baseband signaling or broadband signaling techniques, including carrier wave signaling techniques, such as over computer or telephone networks via a modem, or via any of the networks known. A diagram is shown illustrating an example of a computer that may be used in connection with the present inventions. The computer may include at least one processor and at least one memory, each of which may be coupled to a local interface or bus. An operating system may be stored in the memory and executable by the processor.

Any variety of software programs may also be stored in the memory and executable by the processor. In a specific embodiment, examples of programs that may be stored in the memory and executable by the processor. A media player application may be stored in the memory and executable by the processor. Also stored in the memory may be various forms of data. The term “executable” as used herein means that a program file is of the type that may be run by the processor. In specific embodiments, examples of executable programs may include without limitation: a compiled program that can be translated into machine code in a format that can be loaded into a random access portion of the memory and run by the processor; source code that may be expressed in proper format such as object code that is capable of being loaded into a random access portion of the memory and executed by the processor; or source code that may be interpreted by another executable program to generate instructions in a random access portion of the memory to be executed by the processor. An executable program may be stored in any portion or component of the memory including, for example, random access memory (RAM), read-only memory (ROM), hard drive, solid-state drive, USB flash drive, memory card, optical disc such as compact disc (CD) or digital versatile disc (DVD), floppy disk, magnetic tape, or other memory components. The memory may include both volatile and nonvolatile memory and data storage components.

Volatile components are those that do not retain data values upon loss of power. Nonvolatile components are those that retain data upon a loss of power. Thus, the memory may comprise, for example, random access memory (RAM), read-only memory (ROM), hard disk drives, solid-state drives, USB flash drives, memory cards accessed via a memory card reader, floppy disks accessed via an associated floppy disk drive, optical discs accessed via an optical disc drive, magnetic tapes accessed via an appropriate tape drive, and/or other memory components, or a combination of any two or more of these memory components. In addition, the RAM may comprise, for example, static random-access memory (SRAM), dynamic random-access memory (DRAM), or magnetic random-access memory (MRAM) and other such devices. The ROM may comprise, for example, a programmable read-only memory (PROM), an erasable programmable read-only memory (EPROM), an electrically erasable programmable read-only memory (EEPROM), or other like memory device. In a specific embodiment, the processor may represent multiple processors and/or multiple processor cores and the memory may represent multiple memories that operate in parallel processing circuits, respectively. In such a case, the local interface may be an appropriate network that facilitates communication between any two of the multiple processors, between any processor and any of the memories, or between any two of the memories. The local interface may comprise additional systems designed to coordinate this communication, including, for example, performing load balancing. The processor may be of electrical or of some other available construction.

Although the programs and other various systems, components and functionalities described herein may be embodied in software or code executed by general purpose hardware as discussed above, as an alternative the same may also be embodied in dedicated hardware or a combination of software/general purpose hardware and dedicated hardware. If embodied in dedicated hardware, each can be implemented as a circuit or state machine that employs any one of or a combination of a number of technologies. These technologies may include, but are not limited to, discrete logic circuits having logic gates for implementing various logic functions upon an application of one or more data signals, application specific integrated circuits (ASICs) having appropriate logic gates, field-programmable gate arrays (FPGAs), or other components. Such technologies are generally well known by those skilled in the art and, consequently, are not described in detail herein.

The program instructions may be embodied in the form of source code that comprises human-readable statements written in a programming language or machine code that comprises numerical instructions recognizable by a suitable execution system such as a processor in a computer system or other system. The machine code may be converted from the source code, etc. If embodied in hardware, each block may represent a circuit or a number of interconnected circuits to implement the specified logical function(s). Although the flowchart of FIG. 2 shows a specific order of execution, it is understood that the order of execution may differ from that which is depicted. For example, the order of execution of two or more blocks may be scrambled relative to the order shown.

In addition, any number of counters, state variables, warning semaphores, or messages might be added to the logical flow described herein, for purposes of enhanced utility, accounting, performance measurement, or providing troubleshooting aids. It is understood that all such variations are within the scope of the present inventions. Any logic or application described herein that comprises software or code can be embodied in any non-transitory computer-readable medium, such as computer-readable medium, for use by or in connection with an instruction execution system such as, for example, a processor in a computer system or other system. In this sense, the logic may comprise, for example, statements including instructions and declarations that can be fetched from the computer-readable medium and executed by the instruction execution system. In the context of the present inventions, a “computer-readable medium” may include any medium that may contain, store, or maintain the logic or application described herein for use by or in connection with the instruction execution system.

The computer-readable medium may comprise any one of many physical media such as, for example, magnetic, optical, or semiconductor media. More specific examples of a suitable computer-readable medium would include, but are not limited to, magnetic tapes, magnetic floppy diskettes, magnetic hard drives, memory cards, solid-state drives, USB flash drives, or optical discs. Also, the computer-readable medium may be a random-access memory (RAM) including, for example, static random-access memory (SRAM) and dynamic random-access memory (DRAM), or magnetic random-access memory (MRAM). In addition, the computer-readable medium may be a read-only memory (ROM), a programmable read-only memory (PROM), an erasable programmable read-only memory (EPROM), an electrically erasable programmable read-only memory (EEPROM), or other type of memory device. The computer may further include a network interface coupled to the bus and in communication with a network. The network interface may be configured to allow data to be exchanged between computer and other devices attached to the network or any other network or between nodes of any computer system or the video system. In addition to the above description of the network, it may in various embodiments include one or more networks including but not limited to Local Area Networks (LANs) (e.g., an Ethernet or corporate network), Wide Area Networks (WANs) (e.g., the Internet), wireless data networks, some other electronic data network, or some combination thereof. In various embodiments, the network interface may support communication via wired or wireless general data networks, such as any suitable type of Ethernet network, for example; via telecommunications/telephony networks such as analog voice networks or digital fiber communications networks; via storage area networks such as Fibre Channel SANs, or via any other suitable type of network and/or protocol. The computer may also include an input/output interface coupled to the bus and also coupled to one or more input/output devices, such as a display, a touchscreen, a mouse or other cursor control device, and/or a keyboard. In certain specific embodiments, further examples of input/output devices may include one or more display terminals, keypads, touchpads, scanning devices, voice or optical recognition devices, or any other devices suitable for entering or accessing data by one or more computers. Multiple input/output devices may be present with respect to a computer or may be distributed on various nodes of computer system, the system and/or any of the viewing or other devices. In some embodiments, similar input/output devices may be separate from the computer and may interact with the compute or one or more nodes of computer system through a wired or wireless connection, such as through the network interface. It is to be understood that the inventions disclosed herein are not limited to the exact details of construction, operation, exact materials or embodiments shown and described. Although specific embodiments of the inventions have been described, various modifications, alterations, alternative constructions, and equivalents are also encompassed within the scope of the inventions. Although the present inventions may have been described using a particular series of steps, it should be apparent to those skilled in the art that the scope of the present inventions is not limited to the described series of steps. The specification and drawings are, accordingly, to be regarded in an illustrative rather than a restrictive sense. It will be evident that additions, subtractions, deletions, and other modifications and changes may be made thereunto without departing from the broader spirit and scope of the inventions as set forth in the claims set forth below. Accordingly, the inventions are therefore to be limited only by the scope of the appended claims. None of the claim language should be interpreted pursuant to 35 U.S.C. 112(f) unless the word “means” is recited in any of the claim language, and then only with respect to any recited “means” limitation.

1. A system for providing power to a down hole electrical submersible pump, the system comprising:
a modular 560 kVA power source drive comprising a first 260 kVA drive module and a second 260 kVa drive module;
a first substantially optimized sine wave filter on the load side of the first 260 kVA drive and a second substantially optimized sine wave filter on the load side of the second 260 kVA drive; and
two harmonic filters, a first one on a first harmonic filter integrated into the first 260 kVA drive module and a second harmonic filter on the second 260 kVA.

2. The system of claim 1, wherein the substantially optimized sine wave filter further comprises a sine wave resistor and a sine wave capacitor.

3. The system of claim 2, wherein the sine wave capacitor is not grounded.

4. The system of claim 1, the system further comprising:
a step up transformer having a step up transformer impedance, wherein the step up transformer impedance of is factored into the substantially optimized sine wave filter.

5. The system of claim 1, wherein the substantially optimized sine wave filter is provided that specifies the impedance of the step up transformer which is part of the electrical characteristics of the load side of the drive supplying power to an electric submersible pump.

6. The system of claim 5, wherein the substantially optimized sine wave filter accounts for the impedance of the step up transformer, treating the impedance of the step up transformer as a second series reactor that cleans up power and electrical characteristics of the power supplied from the drive to the electric submersible pump and substantially extends a run life of the electric submersible pump.

7. The system of claim 1, the system further comprising:
a processor in data communication with a computer readable medium; and
a computer program stored in the computer readable medium containing instructions executed by the processor, the computer program comprising instructions to configure the system for declining production requirements by switching out one of the two 260 kVA drives.

8. The system of claim 7, the computer program further comprising:
instructions to control a vendor specific sensor.

9. The system of claim 7, the computer program further comprising:
instructions to send commands and receive data from sensors down hole.

10. The system of claim 9, the computer program further comprising:
instructions to read a MODBUS profile for a replacement sensor from a particular vendor protocol.

11. A system for reducing motor bearing fluting in a down hole electric submersible pump, the apparatus comprising:
a downhole electrical submersible pump deployed downhole in a wellbore drilled in a surface of the Earth, wherein the downhole electrical submersible pump is connected to a surface mounted line-to-ground filter by an electrical cable attached between the surface-mounted line-to-ground filter and the electrical submersible pump; a pulse width modulated three-phase power supply is a modular 560 kVA power source drive comprising a first 260 kVA drive module and a second 260 kVa drive module a substantially optimized sine wave filter on the load side of the first 260 kVA drive and on the load side of the second 260 kVA drive that generate a pulse width modulated three-phase low voltage waveform from a pulse width modulated power supply output to provide power to the downhole electric submersible pump;
a substantially optimized sine wave filter electrically connected to the pulse width modulated power supply output, wherein the sine wave filter generates a three-phase sinusoidal voltage waveform at a nominal low voltage and provides the three-phase sinusoidal voltage waveform from a substantially optimized sine wave filter output on the substantially optimized sine wave filter; a step-up transformer having a low side, wherein the low side is electrically connected to the output of the substantially optimized sine waver filter and receives the three-phase sinusoidal voltage waveform, the step-up transformer further having a high side, wherein the step-up transformer transforms the three-phase sinusoidal voltage waveform received on the low side to a higher medium voltage waveform on the high side wherein the step up transformer impedance of is factored into the substantially optimized sine wave filter; a line-to-ground filter electrically connected between an electrical ground and the three-phase medium voltage on the high side of the step-up transformer, the line-to-ground filter comprising: a common mode filter, the common mode filter comprising, a capacitor, the capacitor having a first and second end, wherein the first end of the capacitor is grounded; a plurality of resistors, wherein the plurality of resistors are each connected to the second end of the capacitor, wherein the plurality of resistors comprises a first, second and third resistor, wherein a first end of the first resistor is connected in series to the second end of the capacitor and connected to a first phase of the three-phase medium voltage, a second resistor connected in series to a second phase of the three-phase medium voltage wherein a first end of the second resistor is connected in series to the second end of the capacitor and a third resistor connected in series to a third phase of the three-phase medium voltage, wherein a first end of the third resistor is connected in series to the second end of the capacitor, wherein the first, second and third resistors each have a first end connected to the capacitor and a second end that receives one phase of the three-phase medium voltage waveform, wherein the three-phase medium voltage waveform contains high voltage high frequency voltage spikes, from the step-up transformer and wherein the line-to-ground filter and supplies the filtered medium voltage waveform to an electric submersible pump deployed down hole in a wellbore, wherein the filtered medium voltage waveform is provided to an extended length of an electrical cable and wherein the line-to-ground filer substantially wherein the line-to-ground filter generates a filtered medium voltage waveform to the electric submersible pump, the filtered medium voltage having substantially reduced high voltage high frequency spikes which substantially reduces bearing fluting in motor bearings in the electric submersible pump caused by the high voltage high frequency voltage spikes.

12. The system of claim 11, wherein the substantially optimized sine wave filter further comprises a substantially optimized sine wave filter resistor and a substantially optimized sine wave filter capacitor for filtering line to line.

13. The system of claim 12, wherein the sine wave filter capacitor is not grounded.

14. The system of claim 11, the system further comprising:
a first substantially optimized sine wave filter on the load side of the first 260 kVA drive and a second substantially optimized sine wave filter on the load side of the second 260 kVA drive.

15. The system of claim 11, further comprising:
two harmonic filters, a first one on a first harmonic filter integrated into the first 260 kVA drive module and a second harmonic filter on the second 260 kVA drive module.

16. The system of claim 11, the system further comprising:
a processor in data communication with a computer readable medium; and
a computer program stored in the computer readable medium containing instructions executed by the processor, the computer program comprising instructions to configure the system for declining production requirements by switching out one of the two 260 kVA drives.

17. The system of claim 16, the computer program further comprising:
instructions to control a vendor specific sensor.

18. The system of claim 17, the computer program further comprising:
instructions to control a vendor specific sensor.

19. The system of claim 17, the computer program further comprising:
instructions to send commands and receive data from sensors down hole.

20. A system for providing power to a down hole electrical submersible pump, the system comprising:
a modular 560 kVA power source drive comprising a first 260 kVA drive module and a second 260 kVa drive module; and
a first substantially optimized sine wave filter on the load side of the first 260 kVA drive and a second substantially optimized sine wave filter on the load side of the second 260 kVA drive.
